(19) United States
(12) Patent Application Publication
(10) Pub. No.: US 2005/0087225 A1
(43) Pub. Date: Apr. 28, 2005

(54) Photovoltaic device

(75) Inventors: Hisao Morooka, Tokyo (JP); Kazuo Nishi, Kanagawa (JP)

Correspondence Address: OLIFF & BERRIDGE, PLC, P.O. BOX 19928, ALEXANDRIA, VA, 22320, US

(73) Assignees: TDK Corporation, Chuo-ku, Tokyo (JP); Semiconductor Energy Laboratory, Atsugi-shi, Kanagawa (JP)

(21) Appl. No.: 10/500,934

(22) PCT Filed: Jan. 10, 2003
(86) PCT No.: PCT/JP03/00167

(30) Foreign Application Priority Data
Jan. 10, 2002 (JP) 2002-3725

(51) Int. Cl. H01L 31/00

(52) U.S. Cl. 136/256

(57) ABSTRACT

On a substrate 1 is formed a first transparent electrode layer 3, on which a p-type semiconductor film 5, an i-type semiconductor film 6 and an n-type semiconductor film 7 are successively formed to constitute an electric power generating layer. On the n-type semiconductor film 7 is formed a second transparent electrode layer 8, on which a back electrode layer 9 is formed. Moreover, an intermediate layer 4 made of a given material is formed between the first transparent electrode layer 3 and the p-type semiconductor film 5 to complete a photovoltaic element 40 with high electric power generating efficiency (conversion efficiency).

### TECHNICAL FIELD

This invention relates to a photovoltaic element which is preferably usable as a semiconductor element composing a solar battery and the like.

### BACKGROUND ART

A photovoltaic element which is fabricated by means of vapor phase method is promised as a low cost thin film solar battery, and vast researches and developments are carried out for the photovoltaic element. As of now, such a photovoltaic element as described hereinafter has been researched and developed.

FIG. 1 is a structural view illustrating a conventional photovoltaic element. The photovoltaic element 1 illustrated in FIG. 1 includes a substrate 1 made of transparent material such as glass, polyethylene naphtalate (PEN), polyethersulfone (PES), polyethylene terephtalate (PET), a first transparent electrode layer 3 formed on the substrate 1, a p-type semiconductor film 5, an i-type semiconductor film 6 and an n-type semiconductor film 7 which are formed successively on the transparent electrode layer 3. The p-type semiconductor film 5, the i-type semiconductor film 6 and the n-type semiconductor film 7 constitute an electric power generating layer. On the n-type semiconductor film 7 is formed a second transparent electrode layer 8, on which a back electrode layer 9 is formed of aluminum, silver, titanium or the like.

In the photovoltaic element 10 illustrated in FIG. 1, as designated by the arrow A, a light is introduced into the photovoltaic element 10 via the substrate 1, and reflected multiply between the substrate 1 and the back electrode layer 9 to generate an electric power effectively and efficiently at the electric power generating layer constituted by the p-type semiconductor film 5, the i-type semiconductor film 6 and the n-type semiconductor film 7.

FIG. 2 is a structural view illustrating another conventional photovoltaic element. In FIGS. 1 and 2, same reference numerals are given to like or corresponding components. In the photovoltaic element 20 illustrated in FIG. 2, on a substrate 11 made of metallic material such as aluminum, silver or titanium are successively formed a first transparent electrode 3, an n-type semiconductor film 7, an i-type semiconductor film 6, an p-type semiconductor film 5 and a second transparent electrode layer 8. In this case, as designated by the arrow B, a light is introduced into the photovoltaic element 20 via the second transparent electrode layer 8, and reflected multiply between the second transparent electrode layer 8 and the substrate 11 to generate an electric power effectively and efficiently at the electric power generating layer constituted by the n-type semi-conductor film 7, the i-type semiconductor film 6 and the p-type semiconductor film 5.

FIG. 3 is a structural view illustrating still another conventional photovoltaic element. In FIGS. 1-3, same reference numerals are given to like or corresponding components. In the photovoltaic element 30 illustrated in FIG. 3, a second substrate 2 made of metallic material is formed on a first substrate 1 made of transparent material. On the second substrate 2 are successively formed a first transparent electrode layer 3, an n-type semiconductor film 7, an i-type semiconductor film 6, a p-type semiconductor film 5 and a second transparent electrode film 8. In this case, too, as designated by the arrow C, a light is introduced into the photovoltaic element 30 via the second transparent electrode layer 8, and reflected multiply between the transparent electrode layer 8 and the first substrate 1; the second substrate 2 to generate an electric power effective and efficiently at the electric power generating layer constituted by the n-type semiconductor film 7, the i-type semiconductor film 6 and the p-type semiconductor film 5.

Herein, in the photovoltaic elements 10, 20 and 30, the p-type semi-conductor film 5, the i-type semiconductor film 6 and the n-type semiconductor film 7, which constitute the electric power generating layer, are made of amorphous silicon. Into the p-type semiconductor film 5 is doped boron, and into the n-type semiconductor film 7 is doped phosphor.

In the photovoltaic elements 10, 20 and 30 illustrated in FIGS. 1-3, however, the electric power generating efficiencies are not sufficient, so that the photovoltaic elements can not be employed as practical thin film solar batteries.

### DESCRIPTION OF THE INVENTION

It is an object of the present invention to develop the electric power generating efficiency (conversion efficiency) of a photovoltaic element which comprises a substrate, a first transparent electrode layer formed on the substrate, an electric power generating layer formed on the first transparent electrode layer, and a second transparent electrode layer formed on the electric power generating layer so that the photovoltaic element can be employed as a practical thin film solar battery. Herein, the electric power generating layer is constituted by a first conduction type semiconductor film, an intrinsic semiconductor film, and a second conduction type semiconductor film different in conduction type from the first conduction type semiconductor film which are successively formed.

For achieving the above object, this invention relates to a photovoltaic element comprising:
a substrate,
a first transparent electrode layer formed on the substrate,
an electric power generating layer formed on the first transparent electrode layer, the electric power generating layer being constituted by a first conduction type semiconductor film, an intrinsic semiconductor film and a second conduction type semiconductor film different in conduction type from the first conduction type semiconductor film,
an second transparent electrode layer formed on the electric power generating layer, and
an intermediate layer made of a given material except oxide between the first transparent electrode layer and the electric power generating layer.

The inventors have intensely studied to develop the electric power generating efficiencies (conversion efficiencies) of the photovoltaic elements 10, 20 and 30 illustrated in FIGS. 1-3 so that the photovoltaic elements can be employed as a practical thin film solar battery. Then, the inventors have found out that when in the photovoltaic elements 10, 20 and 30, instead of the first transparent electrode layer, a metallic electrode layer is employed, the electric power generating efficiencies of the photovoltaic elements 10, 20 and 30 can be enhanced sufficiently so that the low electric power generating efficiencies of the photovoltaic elements 10, 20 and 30 result from the transparent electrode layer.

As mentioned above, the semiconductor films constituting the electric power generating layer are made of amorphous silicon by means of plasma CVD using silane gas and hydrogen gas. In this case, in order to improve the qualities of the semiconductor films, a larger amount of hydrogen gas are employed than the silane gas. Therefore, much hydrogen gas are converted to reactive hydrogen ions and hydrogen radicals in the plasma atmosphere.

On the other hand, since the semiconductor films are formed on the transparent electrode layer, the transparent electrode layer is exposed to the plasma atmosphere containing the hydrogen ions and the hydrogen radicals. As a result, the surface region of the transparent electrode layer are dissociated into the components thereof. The dissociated components are partially incorporated in the plasma atmosphere, so that the semiconductor films contain the components as impurities in addition to the silane gas elements and the hydrogen gas elements.

Then, particularly, since the transparent electrode layer contains oxygen elements as components, the oxygen elements are partially contained in the plasma atmosphere, so that the qualities of the semiconductor films are deteriorated and thus, the electric power generating efficiency of the intended photovoltaic element is also deteriorated.

As a result, according to the present invention, the inventors have found out that by forming an intermediate layer between the transparent electrode layer as an underlayer and a plurality of semiconductor films constituting the electric power generating layer, the dissociation of the transparent electrode layer by the plasma can be prevented. In this case, it is considered that the intermediate layer functions as a passivating layer against the plasma.

It is disclosed in Japanese patent application Laid-open No. 2-109375 that a tantalum oxide thin film is formed between the transparent electrode layer and the p-type semiconductor film to function as a passivating film for the transparent electrode layer. It is also disclosed in Japanese patent application Laid-open No. 2001-60703 that a thin film made of an oxide composed of at least one selected from the group consisting of zinc, titanium, antimony, zirconium, silicon, niobium, aluminum, iron or chromium and tin, and having a thickness of 1-10% of the thickness of the transparent electrode layer is employed as a protection film for the transparent electrode layer.

Although the thin films disclosed in the conventional techniques correspond to the intermediate layer of the photovoltaic element of the present invention, if the thin films are employed as the intermediate layer and the thickness of the intermediate layer is increased in order to enhance the protecting functions thereof, the resistance of the photovoltaic element may be increased remarkably, and the various performances such as conversion efficiency may be deteriorated. As a result, even though the conventional thin film is formed as the intermediate layer in order to impart the passivating function to the transparent electrode layer, the performances of the photovoltaic element can not be enhanced as designed initially.

Moreover, in order to prevent the dissociation of the transparent electrode layer by the plasma, various materials are researched and developed for the transparent electrode layer, but not sufficient.

As illustrated in FIG. 1, when the substrate is made of a given transparent material, and the back electrode layer is formed of a metallic material on the second transparent electrode layer, it is desired that the intermediate layer is made of a metal composed of at least one selected from the group consisting of Fe, Ni, Cr, W, Ti, Ag, Ta and Mo or a silicide composed of at least one selected from the group consisting of Fe, V, Mn, Co, Zr, Nb, Pt, Ni, Cr, W, Ti, Ta and Mo (first photovoltaic element). In this case, the light is introduced into the photovoltaic element, and reflected multiply and more effectively, so that the electric power generating efficiency of the photovoltaic element can be enhanced, and the performances such as fill factor (FF) of the photovoltaic element can be improved.

Moreover, as illustrated in FIG. 2, when the substrate is made of a given metallic material, it is desired that the intermediate layer is made of a metal composed of at least one selected from the group consisting of Fe, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo (second photovoltaic element). In this case, too, the light is introduced into the photovoltaic element, and reflected multiply and more effectively, so that the electric power generating efficiency of the photovoltaic element can be enhanced, and the performances such as fill factor (FF) of the photovoltaic element can be improved.

In addition, as illustrated in FIG. 3, when the substrate is made of the first substrate of a given transparent and the second substrate of a given metallic material, it is desired that the intermediate layer is made of a metal composed of at least one selected from the group consisting of Fe, V, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo (third photovoltaic element). In this case, too, the light is introduced into the photovoltaic element, and reflected multiply and more effectively, so that the electric power generating efficiency of the photovoltaic element can be enhanced, and the performances such as fill factor (FF) of the photovoltaic element can be improved.

### BRIEF DESCRIPTION OF DRAWINGS

FIG. 1 is a structural view illustrating a conventional photovoltaic element.

FIG. 2 is a structural view illustrating another conventional photovoltaic element.

FIG. 3 is a structural view illustrating still another conventional photovoltaic element.

FIG. 4 is a structural view illustrating a photovoltaic element according to the present invention.

FIG. 5 is a structural view illustrating another photovoltaic element according to the present invention.

FIG. 6 is a structural view illustrating still another photovoltaic element according to the present invention.

FIG. 7 is a graph illustrating high temperature-resistance experimental results of the photovoltaic element.

FIG. 8 is a graph illustrating the conversion efficiency (Eff) of the photovoltaic element and the thickness of the intermediate layer.

### BEST MODE FOR CARRYING OUT THE INVENTION

The invention will be described in detail, hereinafter, with reference to the above drawings.

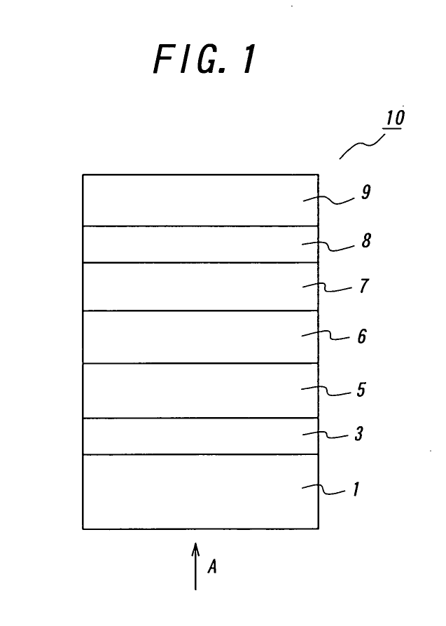

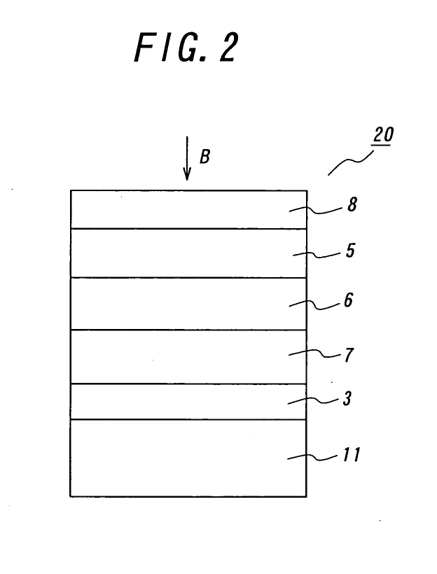

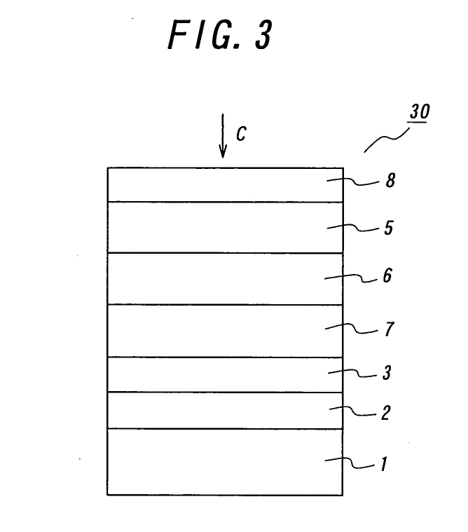

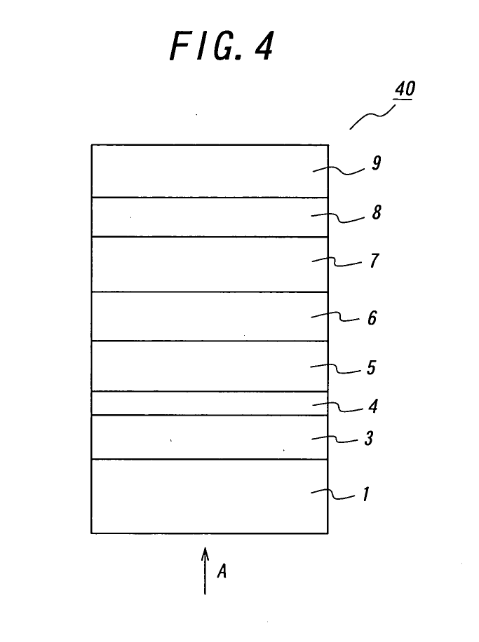

FIG. 4 is a structural view illustrating a photovoltaic element according to the present invention. Through FIGS. 1-4, same reference numerals are given to like or corresponding components. The photovoltaic element 40 illustrated in FIG. 4 includes a substrate 1, a first transparent electrode layer 3 formed on the substrate 1, a p-type semiconductor film 5, an i-type semiconductor film 6 and an n-type semiconductor film 7 which are formed successively on the transparent electrode layer 3. The p-type semiconductor film 5, the i-type semiconductor film 6 and the n-type semiconductor film 7 constitute an electric power generating layer. On the n-type semiconductor film 7 is formed a second transparent electrode layer 8, on which a back electrode layer 9 is formed of aluminum, silver, titanium or the like. Moreover, an intermediate layer 4 is formed of a given material except oxide between the first transparent electrode layer 3 and the p-type semiconductor film 5 composing the electric power generating layer.

As mentioned previously, the substrate 1 is made of a transparent material such as polyethylene naphtalate (PEN), polyethersulfone (PES), polyethylene terephtalate (PET). In view of productivity, a film made of organic resin such as PEN, PES or PET may be preferably employed. The back electrode layer 8 is made of metallic material such as aluminum, silver or titanium. In this case, the intermediate layer 4 is made of a metal composed of at least one selected from the group consisting of Fe, Ni, Cr, W, Ti, Ag, Ta and Mo or a silicide composed of at least one selected from the group consisting of Fe, V, Mn, Co, Zr, Nb, Pt, Ni, Cr, W, Ti, Ta and Mo (first photovoltaic element). In this case, the light is introduced into the photovoltaic element as designated by the arrow A, and reflected multiply and more effectively, so that the electric power generating efficiency of the photovoltaic element can be enhanced, and the performances such as fill factor (FF) of the photovoltaic element can be improved.

The p-type semiconductor film 5, the i-type semiconductor film 6 and the n-type semiconductor film 7, which constitute the electric power generating layer, may be made of amorphous silicon. First of all, therefore, if the intermediate is made of the metallic material as mentioned above and thermally treated, the intermediate layer can contain silicide through the diffusion of silicon particles from the adjacent electric power generating layer.

The thickness of the intermediate layer 4 is not restricted only if in the formation of each semiconductor layer of the electric power generating layer using plasma CVD, the intermediate layer 4 can function as a passivating film against the plasma. The upper limit of the thickness of the intermediate layer 4, however, is preferably set to 10 nm, and the lower limit of the thickness of the intermediate layer 4 is preferably set to 0.5 nm, more preferably 2 nm.

In this case, the intermediate layer 4 can function as passivating film stably, irrespective of the forming method and the forming condition. If the thickness of the intermediate layer 4 is smaller than 0.5 nm, the intermediate layer 4 can not function as a barrier layer against impurities such as oxygen elements. If the thickness of the intermediate layer 4 is larger than 20 nm, the transmissivity of the photovoltaic element may be deteriorated entirely.

The intermediate layer 4 can be made by means of well known film forming method such as sputtering, vacuum deposition or CVD.

As mentioned previously, the p-type semiconductor film 5, the i-type semiconductor film 6 and the n-type semiconductor film 7, which constitute the electric power generating layer, may be made of amorphous silicon by means of plasma CVD. The semiconductor films 5, 6, and 7 may be also made of amorphous silicon by means of catalytic CVD using hot-filament.

With the catalytic CVD method, a raw material gas is contacted with the hot-filament to generate reactive radicals. Therefore, if the reactive radicals are contacted with the transparent electrode layer 3, the surface region of the transparent electrode layer 3 is dissociated into components, and thus, the electric power generating efficiency of the photovoltaic element 40 may be deteriorated due to the dissociated oxygen elements. As a result, it is turned out that in the formation of the electric power generating layer using the catalytic CVD method in addition to the plasma CVD method, the intermediate layer 4 can function as a passivating film.

Herein, the thickness of the p-type semiconductor film 5 is set within 10-20 nm, and the thickness of the i-type semiconductor film 6 is set within 350-450 nm, and the thickness of the n-type semiconductor film 7 is set within 20-40 nm.

In the first photovoltaic element, the first transparent electrode layer 3 may be made of, e.g., SnO, ITO or ZnO, and the thickness of the first transparent electrode layer 3 is set within 60-80 nm. The second transparent electrode layer 8 may be also made of, e.g., SnO, ITO or ZnO, and the thickness of the second transparent electrode layer 8 is set within 60-80 nm. The thickness of the back electrode layer 9 is set within 200-400 nm.

The first transparent electrode layer 3, the second transparent electrode layer 8 and the back electrode layer 9 may be made by means of well known film forming method such as sputtering, vacuum deposition or CVD.

In view of electric power generating efficiency using multiple reflection, particularly, the first transparent electrode 3 is preferably made of ZnO, and the second transparent electrode 8 is preferably made of ITO.

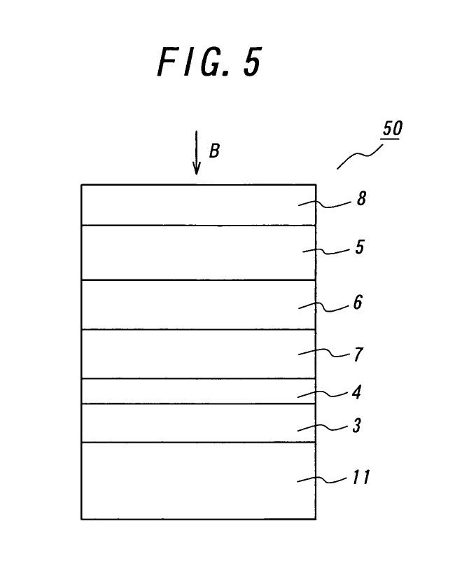

FIG. 5 is a structural view illustrating another photovoltaic element according to the present invention. Through FIGS. 1-5, same reference numerals are given to like or corresponding components. The photovoltaic element 50 illustrated in FIG. 5 includes a substrate 11, a first transparent electrode layer 3 formed on the substrate 11, an n-type semiconductor film 7, an i-type semi-conductor film 6, a p-type semiconductor film 5 and a second transparent electrode layer 8 which are formed successively on the transparent electrode layer 3. Then, an intermediate layer 4 is formed of a given material between the first transparent electrode layer 3 and the n-type semiconductor film 7.

As mentioned previously, the substrate 11 is made of a metallic material such as stainless steel, aluminum, silver or titanium. In view of productivity, particularly, the substrate 11 is preferably made of a stainless foil. In this case, the intermediate layer 4 is made of a metal composed of at least one selected from the group consisting of Fe, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo (second photovoltaic element). In this case, too, the light is introduced into the photovoltaic element as designated by the arrow B, and reflected multiply and more effectively, so that the electric power generating efficiency of the photovoltaic element can be enhanced, and the performances such as fill factor (FF) of the photovoltaic element can be improved.

The thickness of the intermediate layer 4 is set equal to the one of the first photovoltaic element on the same reason and the intermediate layer 4 can be made in the same manner as the first photovoltaic element.

The n-type semiconductor film 7, the i-type semiconductor film 6 and the p-type semiconductor film 5, which constitute the electric power generating layer, may be made of amorphous silicon by means of plasma CVD or catalytic CVD. The thickness of the n-type semiconductor film 7 is set within 20-40 nm, and the thickness of the p-type semiconductor film 5 is set within 350-450 nm, and the thickness of the p-type semiconductor film 5 is set within 10-20 nm.

The first transparent electrode layer 3 is made of a well known transparent material such as SnO, ITO or ZnO, and the thickness of the first transparent electrode layer 3 is set within 60-80 nm. The second transparent electrode layer 8 is also made of a well known transparent material such as SnO, ITO or ZnO, and the thickness of the first transparent electrode layer 3 is also set within 60-80 nm. The first transparent electrode layer 3 and the second transparent electrode layer 8 may be made by means of well known film forming method such as sputtering, vacuum deposition and CVD.

In view of electric power generating efficiency using multiple reflection, the first transparent electrode layer 3 may be preferably made of ZnO, and the second transparent electrode layer 8 may be preferably made of ITO.

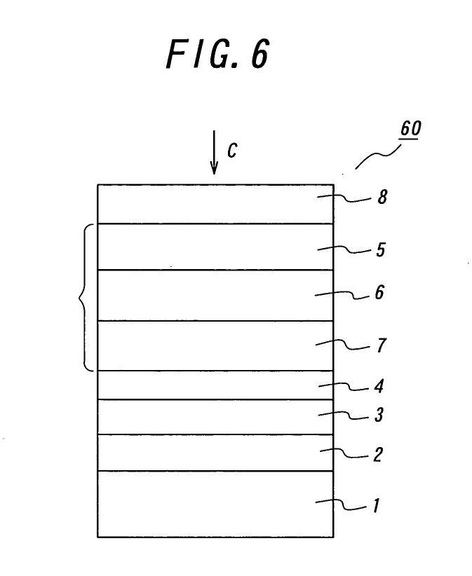

FIG. 6 is a structural view illustrating still another photovoltaic element according to the present invention. Through FIGS. 1-6, same reference numerals are given to like or corresponding components. The photovoltaic element 60 illustrated in FIG. 6 includes a first substrate 1, a second substrate 2 formed on the first substrate 1, and the first transparent electrode layer 3 on the second substrate 2. On the first transparent electrode layer 3 are successively formed an n-type semiconductor film 7, an i-type semiconductor film 6, a p-type semiconductor film 5, and a second transparent electrode layer 8. An inter-mediate layer 4 is formed of a given material between the first transparent electrode layer 3 and the n-type semiconductor film 7.

As mentioned previously, the substrate 1 is made of a transparent material such as polyethylene naphtalate (PEN), polyethersulfone (PES), polyethylene terephtalate (PET). In view of productivity, a film made of organic resin such as PEN, PES or PET may be preferably employed. The second substrate 2 is made of metallic material such as stainless steel, aluminum, silver or titanium. In view of productivity, the second substrate 2 is preferably made of a stainless foil.

In this case, the intermediate layer 4 is made of a metal composed of at least one selected from the group consisting of Fe, V, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo (third photovoltaic element). In this case, too, the light is introduced into the photovoltaic element as designated by the arrow C, and reflected multiply and more effectively, so that the electric power generating efficiency of the photovoltaic element can be enhanced, and the performances such as fill factor (FF) of the photovoltaic element can be improved.

The p-type semiconductor film 5, the i-type semiconductor film 6 and the n-type semiconductor film 7, which constitute the electric power generating layer, may be made of amorphous silicon by means of plasma CVD or catalytic CVD. The thickness of the n-type semiconductor film 7 is set within 20-40 nm, and the thickness of the i-type semiconductor film 6 is set within 350-450 nm, and the thickness of the p-type semiconductor film 5 is set within 10-20 nm.

The first transparent electrode layer 3 is made of a well known transparent material such as SnO, ITO or ZnO, and the thickness of the first transparent electrode layer 3 is set within 60-80 nm. The second transparent electrode layer 8 is also made of a well known transparent material such as SnO, ITO or ZnO, and the thickness of the second transparent electrode layer 8 is also set within 60-80 nm. The first transparent electrode layer 3 and the second transparent electrode layer 8 may be made by means of well known film forming method such as sputtering, vacuum deposition and CVD.

In view of electric power generating efficiency using multiple reflection, the first transparent electrode layer 3 may be preferably made of ZnO, and the second transparent electrode layer 8 may be preferably made of ITO.

### EXAMPLES

This invention will be concretely described on the examples.

### Examples 1-3

In these examples, the first photovoltaic element as illustrated in FIG. 4 was fabricated. As a substrate was employed a PEN film with a thickness of 75 μm, which was set in a DC magnetron sputtering apparatus. Then, a ZnO film was formed as the first transparent electrode layer in a thickness of 70 nm. The sputtering was performed under the condition that a ZnO target was employed, and the Ar gas pressured was set to 0.5 Pa, and the input electric power was set to 2.0 W/cm².

Then, Ni films were formed as intermediate layers in thicknesses of 2, 5, 10 nm by the same DC magnetron sputtering apparatus. The sputtering was performed under the condition that a Ni-target was employed, and the Ar gas pressure was set to 0.5 Pa, and the input electric power was set to 0.5 W/cm².

Then, an electric power generating layer is formed by means of plasma CVD. The PEN film with the ZnO film and the Ni film was set into the plasma CVD apparatus, and heated to 160° C. Then, a B₂H₆ gas, an H₂ gas and a SiH₄ gas were introduced into the apparatus at flow rates of 0.02 sccm, 800 sccm and 4 sccm, respectively, under the condition that the gas pressure was 266.6 Pa, and the input electric power was 180 mW/cm² to form, as the p-type semi-conductor film, a p-type boron-doped micro-crystalline silicon film in a thickness of 10 nm.

Then, a SiH₄ gas and an H₂ gas were introduced into the apparatus at flow rates of 50 sccm and 500 sccm, respectively under the condition that the gas pressure was set to 266.6 Pa, and the input electric power was set to 50 mW/cm² to form, as the i-type semiconductor film, an intrinsic amorphous silicon film in a thickness of 400 nm. Then, a PH₃ gas, an H₂ gas and a SiH₄ gas were introduced into the apparatus at flow rates of 0.06 sccm, 500 sccm and 5 sccm, respectively under the condition that the gas pressure was 133.3 Pa and the input electric power was 60 mW/cm to form, as the n-type phosphor doped micro-crystalline silicon film in a thickness of 30 nm.

Then, the PEN film was set in the DC magnetron sputtering apparatus, and an ITO film was formed as a second transparent electrode layer in a thickness of 60 nm. The sputtering was performed under the condition that an ITO target was employed, and the Ar gas pressure was set to 0.4 Pa, and the oxygen gas pressure was set to 0.08 Pa, and the input electric power was set to 0.3 W/cm². Then, an Al film was formed as the back electrode layer under the condition that an Al target was employed, and the Ar gas pressure was set to 0.5 Pa, and the input electric power was set to 2.2 W/cm². The conversion efficiencies (Eff), the fill factors (FF), and the resistances (Rse) along stacking direction of the thus obtained photovoltaic elements were listed in Table 1.

### Comparative Example 1

Except that the intermediate layer is not formed, a photovoltaic element was formed in the same manner as in Examples 1-3. The conversion efficiency (Eff), the fill factor, and the resistance (Rse) along the stacking direction of the thus obtained photovoltaic element were listed in Table 1.

TABLE 1

| | Thickness of | | | |
|---|---|---|---|---|
| | intermediate layer | Eff | | Rse |
| | (nm) | (%) | FF | (Ω) |
| Example 1 | 2 | 6.26 | 0.655 | 25.2 |
| Example 2 | 5 | 6.48 | 0.683 | 23.3 |
| Example 3 | 10 | 6.62 | 0.696 | 20.5 |
| Comparative | 0 | 6.15 | 0.629 | 32 |
| Example 1 | | | | |

As is apparent from Table 1, the conversion efficiencies and the fill factors (FF) of the photovoltaic elements with the Ni films as the intermediate layers relating to Examples 1-3 are increased in comparison with the ones of the photovoltaic element without the intermediate layer, so that the photovoltaic elements with the intermediate layers can be employed as practical thin film solar batteries.

Herein, the resistances in stacking direction of the photovoltaic elements relating to Examples 1-3 are decreased in comparison with the ones of the photovoltaic element relating to Comparative Example 1. It is, therefore, turned out that the intermediate layer prevents the dissociation of the ZnO transparent electrode layer due to the plasma, and each semiconductor layer composing the electric power generating layer is not deteriorated.

When the intermediate layer was made of a Co film or a Ni-50 at % Co alloy film, the same results and phenomena as mentioned above were obtained. Moreover, when the intermediate layer was made of a Ni silicide film by using a target with Ni:Si atomic ratio=1:2, the same results and phenomena as mentioned above were obtained.

### Examples 4-6

In these examples, the third photovoltaic element as illustrated in FIG. 6 was fabricated. As a substrate was employed a PEN film with a thickness of 75 μm, which was set in a DC magnetron sputtering apparatus. Then, an Al film was formed as the second substrate in a thickness of 300 nm. The sputtering was performed under the condition that an Al target was employed, and the Ar gas pressure was set to 0.5 Pa, and the input electric power was 2.2 W/cm². Then, an ZnO film was formed as the first transparent electrode layer in a thickness of 90 nm. The sputtering was performed under the condition that a ZnO target was employed, and the Ar gas pressured was set to 0.5 Pa, and the input electric power was set to 2.0 W/cm².

Then, Ni films were formed as intermediate layers in thicknesses of 2, 5, 10 nm by the same DC magnetron sputtering apparatus. The sputtering was performed under the condition that a Ni-target was employed, and the Ar gas pressure was set to 0.5 Pa, and the input electric power was set to 0.5 W/cm².

Then, an electric power generating layer is formed by means of plasma CVD. The PEN film with the ZnO film and the Ni film was set into the plasma CVD apparatus, and heated to 160° C. Then, a. PH₃ gas, an H₂ gas and a SiH₄ gas were introduced into the apparatus at flow rates of 0.06 sccm, 500 sccm and 5 sccm, respectively under the condition that the gas pressure was 133.3 Pa and the input electric power was 60 mW/cm² to form, as the n-type semiconductor film, an n-type phosphor doped micro-crystalline silicon film in a thickness of 30 nm.

Then, a SiH₄ gas and an H₂ gas were introduced into the apparatus at flow rates of 50 sccm and 500 sccm, respectively under the condition that the gas pressure was set to 266.6 Pa, and the input electric power was set to 50 mW/cm to form, as the i-type semiconductor film, an intrinsic amorphous silicon film in a thickness of 400 nm.

Then, a B₂H₆ gas, an H₂ gas and a SiH₄ gas were introduced into the apparatus at flow rates of 0.02 sccm, 800 sccm and 4 sccm, respectively, under the condition that the gas pressure was 266.6 Pa, and the input electric power was 180 mW/cm² to form, as the p-type semiconductor film, a p-type boron-doped micro-crystalline silicon film in a thickness of 10 nm.

Then, the PEN film was set in the DC magnetron sputtering apparatus, and an ITO film was formed as a second transparent electrode layer in a thickness of 60 nm. The sputtering was performed under the condition that an ITO target was employed, and the Ar gas pressure was set to 0.4 Pa, and the oxygen gas pressure was set to 0.08 Pa, and the input electric power was set to 0.3 W/cm². The conversion efficiencies (Eff), the fill factors (FF), and the resistances (Rse) along stacking direction of the thus obtained photovoltaic elements were listed in Table 1.

### Comparative Example 2

Except that the intermediate layer is not formed, a photovoltaic element was formed in the same manner as in Examples 4-6. The conversion efficiency (Eff), the fill factor (FF), and the resistance (Rse) along stacking direction of the thus obtained photovoltaic element were listed in Table 2.

TABLE 2

| | Thickness of | | | |
|---|---|---|---|---|
| | intermediate layer | Eff | | Rse |
| | (nm) | (%) | FF | (Ω) |
| Example 4 | 2 | 7.60 | 1.668 | 13.3 |
| Example 5 | 5 | 7.73 | 0.683 | 12 |
| Example 6 | 10 | 6.13 | 0.72 | 10.5 |
| Comparative | 0 | 7.44 | 0.638 | 23.9 |
| Example 2 | | | | |

As is apparent from Table 2, the conversion efficiencies and the fill factors of the photovoltaic elements with the Ni films as the intermediate layers relating to Examples 4-6 are increased in comparison with the ones of the photovoltaic element without the intermediate layer, so that the photovoltaic elements with the intermediate layers can be employed as practical thin film solar batteries.

Herein, the resistances in stacking direction of the photovoltaic elements relating to Examples 4-6 are decreased in comparison with the ones of the photovoltaic element relating to Comparative Example 2. It is, therefore, turned out that the intermediate layer prevents the dissociation of the ZnO transparent electrode layer due to the plasma, and each semiconductor layer composing the electric power generating layer is not deteriorated.

When the intermediate layer was made of a Co film or a Ni-50 at % Co alloy film, the same results and phenomena as mentioned above were obtained. Moreover, when the intermediate layer was made of a Ni silicide film by using a target with Ni:Si atomic ratio=1:2, the same results and phenomena as mentioned above were obtained.

### Example 7 and Comparative Example 3

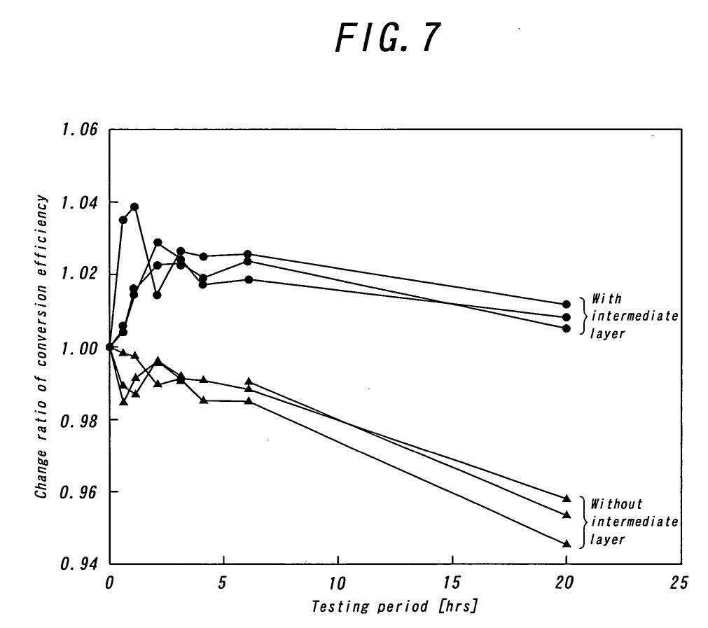

Three photovoltaic elements with their respective intermediate layers made of Ni films were fabricated in the same manner as in Examples 1-3, and three photovoltaic elements with no intermediate layers were fabricated in the same manner as in Comparative Example 1. Then, high temperature-resistance test at 150° C. was performed for the photovoltaic elements. The thus obtained results are plotted in FIG. 7. The ordinate axis designates the change ratio of conversion efficiency as the initial conversion efficiency is set to 1, and the abscissa axis designates the testing period (time). As is apparent from FIG. 7, the change ratio of conversion efficiency of the photovoltaic element with the intermediate layer is smaller than the one of the photovoltaic element with no intermediate layer, so that the each semiconductor film composing the electric power generating layer of the photovoltaic element is not almost deteriorated, and thus, can have long-time reliability.

### Comparative Example 4-7

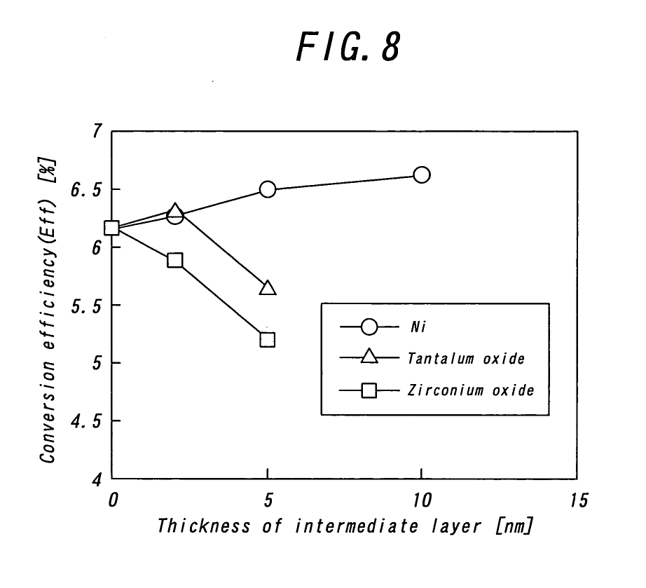

Instead of the Ni intermediate layer, tantalum oxide intermediate layers with thicknesses of 2 nm and 5 nm were employed, and zirconium oxide intermediate layers with thicknesses of 2 nm and 5 nm were employed, to fabricate photovoltaic elements in the same manner as in Examples 1-3. The conversion efficiencies(Eff), the fill factors (FF), and the resistances (Rse) along stacking direction of the thus obtained photovoltaic elements were listed in Table 3, in comparison with the results relating to Examples 1-3. Then, the dependence of the conversion efficiency on the thickness of the intermediate layer was illustrated in FIG. 8.

TABLE 3

| Thickness of | | | |
|---|---|---|---|
| intermediate layer | | | |
| (nm) | Eff | FF | Rse |
| | Ni intermediate | | |
| | layer | | |
| 0 | 6.15 | 0.619 | 32 |
| 2 | 6.26 | 0.655 | 25.2 |
| 5 | 6.48 | 0.683 | 23.3 |
| 10 | 6.62 | 0.696 | 20.5 |
| | Tantalum oxide | | |
| | intermediate layer | | |
| 0 | | | |
| 2 | 6.32 | 0.648 | 28.1 |
| 5 | 5.64 | 0.592 | 43.9 |
| 10 | | | |
| | Zirconium oxide | | |
| | intermediate layer | | |
| 0 | | | |
| 2 | 5.87 | 0.611 | 31.2 |
| 5 | 5.18 | 0.532 | 48.7 |
| 10 | | | |

As is apparent from Table 3 and FIG. 8, in the use of the tantalum oxide intermediate layer and the zirconium oxide intermediate layer, as the thickness of the intermediate layer is increased, the intermediate layer functions as a passivating film more effectively, but the resistance (Rse) in stacking direction of the photovoltaic element is increased, and thus, the conversion efficiency (Eff) of the photovoltaic element is deteriorated. Particularly, as the thickness of the intermediate layer is increased to 5 nm, the conversion efficiency of the photovoltaic element is deteriorated in comparison with the one of the photovoltaic element with no intermediate layer. Moreover, in the use of the zirconium oxide intermediate layer, as the thickness of the intermediate layer is increased only to 2 nm, the conversion efficiency (Eff) of the photovoltaic element is deteriorated, and thus, the performances of the photovoltaic element is not enhanced.

Although the present invention was described in detail with reference to the above examples, this invention is not limited to the above disclosure and every kind of variation and modification may be made without departing from the scope of the present invention. For example, in the photovoltaic element illustrated in FIG 1, the first conduction type semiconductor layer is made of the p-type semiconductor film, and the second conduction type semiconductor layer is made of the n-type semiconductor film, but the other way round will do.

Industrial Applicability

According to the present invention, in the photovoltaic element comprising the substrate, the first transparent electrode layer formed on the substrate, the electric power generating layer formed on the first transparent electrode layer, and the second transparent electrode layer formed on the electric power generating layer, the electric power generating layer being constituted by the first conduction type semiconductor film, the intrinsic semiconductor film and the second conduction type semiconductor film different in conduction type from the first conduction type semiconductor film which are successively formed, since the intermediate layer is formed between the first transparent electrode layer and the electric power generating layer, the qualities of the first conduction type semiconductor film, the intrinsic semiconductor film and the second conduction type semiconductor film constituting the electric power generating layer are not deteriorated, and thus, the electric power generating efficiency (conversion efficiency) of the photovoltaic element can be enhanced. Therefore, the photovoltaic element can be preferably usable as a practical solar battery.

1. A photovoltaic element comprising:
a substrate,
a first transparent electrode layer formed on said substrate,
an electric power generating layer formed on said first transparent electrode layer, said electric power generating layer being constituted by a first conduction type semiconductor film, an intrinsic semiconductor film and a second conduction type semiconductor film different in conduction type from said first conduction type semiconductor film,
an second transparent electrode layer formed on said electric power generating layer, and
an intermediate layer made of a given material except oxide between said first transparent electrode layer and said electric power generating layer.

2. The photovoltaic element as defined in claim 1, wherein a thickness of said intermediate layer is set within 0.5-20 nm.

3. The photovoltaic element as defined in claim 1, further comprising a back electrode layer on said second transparent electrode layer, wherein said substrate is made of a given transparent material and said intermediate layer is made of a metal composed of at least one selected from the group consisting of Fe, Ni, Cr, W, Ti, Ag, Ta and Mo or a silicide composed of at least one selected from the group consisting of Fe, V, Mn, Co, Zr, Nb, Pt, Ni, Cr, W, Ti, Ta and Mo.

4. The photovoltaic element as defined in claim 3, wherein said substrate is made of an organic film.

5. The photovoltaic element as defined in claim 1, wherein said substrate is made of a given metallic material and said intermediate layer is made of a metal composed of at least one selected from the group consisting of Fe, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo.

6. The photovoltaic element as defined in claim 5, wherein said substrate is made of a stainless foil.

7. The photovoltaic element as defined in claim 1, wherein said substrate is composed of a first substrate made of a given transparent material and a second substrate made of a given metallic material, and said intermediate layer is made of a metal composed of at least one selected from the group consisting of Fe, V, Mn, Co, Zr, Nb, Pt, Ni, Cr, W, Ti, Ta and Mo or a silicide composed of at least one selected from the group consisting of Fe, V, Mn, Co, Zr, Nb, Pt, Ni, Cr, W, Ti, Ta and Mo.

8. The photovoltaic element as defined in claim 7, wherein said first substrate is made of an organic film.

9. The photovoltaic element as defined in claim 7, wherein said second substrate is made of a stainless foil.

10. The photovoltaic element as claim 1, wherein said first transparent electrode film is made of a ZnO film.

11. The photovoltaic element as claim 1, wherein said second transparent electrode film is made of an ITO film.

12. The photovoltaic element as claim 1, wherein said electric power generating layer is formed by means of plasma CVD.

13. The photovoltaic element as claim 1, wherein said electric power generating layer is made of amorphous silicon.
